(19) United States
(12) Patent Application Publication
(10) Pub. No.: US 2006/0139040 A1
(43) Pub. Date: Jun. 29, 2006

(54) Non-contact electrical probe utilizing charged fluid droplets

(76) Inventors: Michael James Nystrom, San Jose, CA (US); Daniel B. Roitman, Menlo Park, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 11/020,725

(22) Filed: Dec. 23, 2004

(51) Int. Cl. G01R 31/02

(52) U.S. Cl. 324/754

(57) ABSTRACT

There present invention is directed to a system and method which a liquid dispensing head is positioned above the contact area of the device under test (DUT). Liquid droplets are dispensed form the head and these droplets are charged with an electrical charge so that when the drops form a pool of liquid on the contact area the pool is charged thereby causing current to flow in the DUT. In this manner, for example, the transistor at each pixel of an OLED can be tested. In one embodiment an inkjet head is used to dispense fluid that is subsequently charged. In still another embodiment, the inkjet head is piezoelectric.

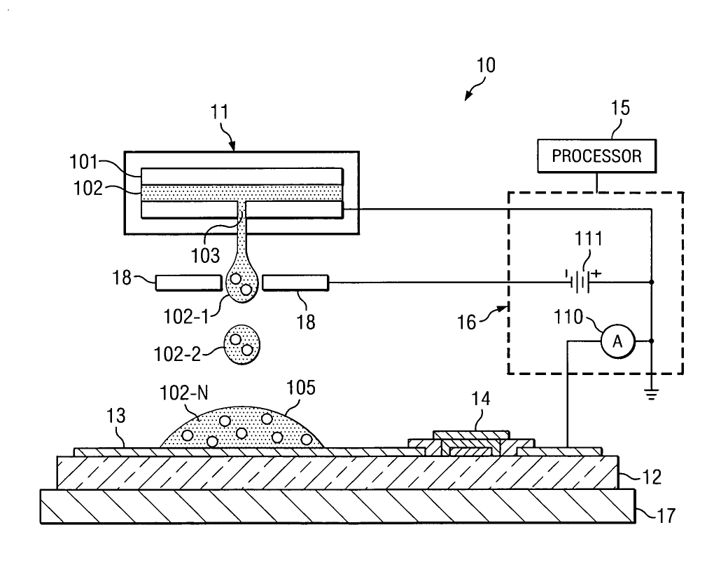

### CROSS-REFERENCE TO RELATED APPLICATIONS

The present application is related to concurrently filed, co-pending, and commonly assigned U.S. patent application Ser. No. ______, Attorney Docket No. 10041036-1, entitled “SYSTEM AND METHOD OF TESTING AND UTILIZING A FLUID STREAM,” and U.S. patent application Ser. No. ______, Attorney Docket No. 10041087-1, entitled “SYSTEMS AND METHODS FOR AN ELECTRICAL PROBING MEDIUM USING AN IONIZED GAS CREATED BY AN ATMOSPHERIC DISCHARGE,” the disclosures of which are hereby incorporated herein by reference.

### BACKGROUND OF THE INVENTION

Organic light emitting diode (OLED) flat panel displays use an emissive flat panel display technology that is an extension of the existing thin film transistor (TFT) liquid crystal display (LCD) technology. While OLED technology is similar to TFT technology, the emissive property of the OLED displays leads to greater complexity, particularly for testing during manufacturing. One difference, as it applies to testing, is that the OLED pixel brightness is controlled with a current signal, as opposed to being controlled with a voltage as are existing LCD displays. This results in the OLED display having one additional transistor per pixel.

To test existing LCD displays, the voltage controlling each pixel can be directly measured even without touching the active area of the display's surface. However, in order to test each pixel of the OLED display, it is necessary to measure current on the display at each pixel also without actually touching the display surface.

While, several techniques are known to sense voltage without actually touching the surface, current sensing without touching presents a problem. For example, voltage can be sensed by using an electron beam to image the surface, such that, voltage differences on the surface show as contrast differences. One technique to measure current is to incorporate an additional capacitor per pixel on the OLED display circuit and to measure the charging of this added capacitor through a resistor. This works because the charging rate of the capacitor is a direct function of the resistance value of the resistor. This technique adds complexity to the circuitry and adds a component that will not be used again after testing.

A second technique is to use an electron beam as a contactless probe. This technique requires placing the OLED in a vacuum chamber which is expense and time consuming.

### BRIEF SUMMARY OF THE INVENTION

The present invention is directed to systems and methods in accordance with the invention in which a liquid dispensing head is positioned above the contact area of the device under test (DUT). Liquid droplets are dispensed from the head and these droplets are charged with an electrical charge so that when the drops form a pool of liquid on the contact area the pool is electrically charged thereby causing current to flow in the DUT. In this manner, for example, the transistor at each pixel of an OLED can be tested.

### BRIEF DESCRIPTION OF THE DRAWINGS

For a more complete understanding of the present invention, reference is now made to the following descriptions taken in conjunction with the accompanying drawing, in which:

The FIGURE shows one embodiment of a test system in accordance with the invention.

### DETAILED DESCRIPTION OF THE INVENTION

One embodiment of test system 10 in accordance with the invention is shown in the FIGURE where test head 11 selectively allows fluid 102 to drip therefrom to form a pool of fluid 105 on a contact pad, such as on contact pad 13, of DUT 12. Contact pad is in contact with device 14 to be tested (in this case the device is a transistor which is part of DUT 12). DUT 12 can be, for example, an OLED display panel, or any other device that must be tested without direct physical contact. Display panel 12, in turn, rests in this embodiment on test bed 17, which can be any type of test bed. In other embodiments display panel 12 can be self-supporting, if desired.

Test head 11 in the embodiment shown is a piezoelectric inkjet head having control element 101, fluid 102, and control orifice 103, which selectively allows fluid 102 to form droplets, such as droplets 102-1, 102-2, 102-N, thereby forming pool 105 on contact 13. Droplets 102 are electrically charged, for example, by passing through an opening in plate 18, and thus, pool 15 is electrically charged, at least for a period of time.

Head 11 can be constructed to form droplets and allow them to fall in free-form through plate 18 or, as shown, each droplet can be part of an elongated stream from which a droplet forms before falling through the orifice in phase 18. In one embodiment, voltage from voltage source 111 is applied to plate 18 which voltage serves to charge each droplet 102 as the droplet passes through plate 18. In an alternative embodiment, liquid in reservoir 102 can be charged before the droplets are formed. Also, each droplet 102 can be changed by an external energy source, such as by light selectively hitting the droplets, before they form pool 105. The droplets fall into pool 105 replenishing the charge on contact pad 13. This charge then is transmitted to the DUT, such as transistor 14, which in turn then allows the current through the transistor to be measured via meter 110.

The fluid must be easy to clean from the contact pad after the measurement. An ionic conductor would be acceptable as would water with ionic impurities. Neither the fluid nor the impurities must react with the contact pad surface and must be readily removed from the surface after the test.

When the test on display panel 12 is complete, the dripping liquid is stopped; the liquid in pool 105 is wiped clean from the surface, the panel is removed, and another panel inserted in its place. In the embodiment, it is contemplated that test head 11 and test bed 17, as well as circuitry, such as control 16, that controls the test sequence, is permanently in place. Alternatively, the system can be hand-held such that the test head is part of a portable device. In such an arrangement droplets can be squirted from head 11 to the DUT for the purpose of measuring current flow through a DUT.

In device 10 droplets are shown falling by gravity from head 11. However, these droplets can be powered by head 11 or by orifice 103 which can operate much like a squeeze bottle to pulse droplets through the orifice. It is contemplated that the distance from orifice 103 to contact 13 will be approximately 100 microns.

Note that while the disclosure has been framed in context to testing an OLED panel, the concepts discussed herein could be used to test any device without actually touching that device.

Also it should be understood that while a single aperture is shown forming a single line of droplets, a plurality of apertures could be used to control multiple lines of droplets, or a single aperture could be used to direct the droplets to different contact locations. If desired, plate 18 could be used to direct the droplets to the proper location.

Although the present invention and its advantages have been described in detail, it should be understood that various changes, substitutions and alterations can be made herein without departing from the invention as defined by the appended claims. Moreover, the scope of the present application is not intended to be limited to the particular embodiments of the process, machine, manufacture, composition of matter, means, methods and steps described in the specification. As one will readily appreciate from the disclosure, processes, machines, manufacture, compositions of matter, means, methods, or steps, presently existing or later to be developed that perform substantially the same finction or achieve substantially the same result as the corresponding embodiments described herein may be utilized. Accordingly, the appended claims are intended to include within their scope such processes, machines, manufacture, compositions of matter, means, methods, or steps.

What is claimed is:

1. A probe comprising:
a dispensing head adapted for being disposed apart from an electrical contact area, said dispensing head holding material capable of receiving an electrical charge; and
a control device for imparting a charge to material dispensed from said dispersing head, said charged material operative for imparting a temporary charge to said electrical contract area.

2. The probe of claim 1 wherein said material is dispensed in droplets.

3. The probe of claim 3 further comprising:
a source of energy to selectively control said charging of said material.

4. The probe of claim 1 wherein said probe further comprises:
at least one input for controlling the dispensing of said material.

5. A method of testing an organic light emitting diode (OLED), said method comprising:
causing a liquid pool to be formed on a contact area of said OLED, said liquid pool creating an electrical charge on said contact area; and
measuring current passing through at least one active element of said OLED as a result of said formed liquid pool.

6. The method of claim 5 wherein said selectively creating comprises:
dispensing droplets of material from a head positioned apart form said contact area.

7. The method of claim 6 wherein said selectively creating further comprises:
selectively charging said droplets prior to said droplets contacting said contact area.

8. A test device comprising:
means for providing test signals;
means for positioning a device under test (DUT); and
means spaced apart from said positioning means for selectively controlling the flow of material therefrom, said selectively controlling means having at least one aperture in line with at least one contact area of a positioned DUT so as to establish an electrical charge on said contact area of said positioned DUT.

9. The test device of claim 8 wherein said charge is created by charging drops of material flowing from said spaced apart controlling means.

10. The test device of claim 9 wherein said material flowing from said space apart means is liquid.

11. The test device of claim 10 wherein said liquid is water with ionic impurities therein.

12. The test device of claim 10 further comprising:
means for controlling test procedures among said test signal providing means, said spaced apart controlling means and a DUT.

13. The test device of claim 10 wherein said test procedures comprise:
means for enabling said selectively controlling means.

14. The test device of claim 10 further comprising:
means for controlling the quantity of material flowing from said aperture.

15. The test device of claim 10 further comprising:
means for controlling said charge.

16. The test device of claim 10 wherein said material flows by the force of gravity.

17. The test device of claim 10 wherein said material is forcibly ejected from said spaced apart means.

18. The test device of claim 10 wherein said spaced apart means comprises:
an inkjet head.

19. The test device of claim 18 wherein said inkjet head comprises:
a piezoelectric inkjet head.

20. The test device of claim 10 wherein said DUT is an OLED.
